(19) United States
(12) Patent Application Publication
(10) Pub. No.: US 2024/0283210 A1
(43) Pub. Date: Aug. 22, 2024

(54) PULSED POWER SYSTEMS WITH CONTROLLED REACTOR RESET

(71) Applicant: Cymer, LLC, San Diego, CA (US)

(72) Inventors: Paul Christopher Melcher, El Cajon, CA (US); Yuda Wang, San Diego, CA (US); Changqi You, San Diego, CA (US)

(21) Appl. No.: 18/568,442

(22) PCT Filed: Jun. 6, 2022
(86) PCT No.: PCT/US2022/032333

§ 371 Date: Dec. 8, 2023

Related U.S. Application Data
(60) Provisional application No. 63/222,074, filed on Jul. 15, 2021.

(51) Int. Cl. H01S 3/097; G03F 7/00; G03F 7/20; H01S 3/083; H01S 3/225; H01S 3/23

(52) U.S. Cl. CPC H01S 3/09702; G03F 7/2004; G03F 7/70025; G03F 7/70041; H01S 3/0835; H01S 3/2308; H01S 3/225; H01S 3/2366

(57) ABSTRACT

A pulsed power circuit including one or more magnetic switches respectively implemented as one or more inductors having saturable cores wherein, after a discharge pulse, each saturable core is repeatably reset to an initial bias point on its magnetization curve by a reset pulse having variable characteristics determined, for example, by chamber operating conditions so that the saturable core is able to function reliably and consistently.

### CROSS REFERENCE TO RELATED APPLICATIONS

This application claims priority to U.S. application Ser. No. 63/222,074, filed Jul. 15, 2021, titled PULSED POWER SYSTEMS WITH CONTROLLED REACTOR RESET, which is incorporated herein in its entirety by reference.

### FIELD

The present disclosure relates to apparatus for generating electrical pulses, for example, in lasers serving as illumination sources in semiconductor photolithography systems.

### BACKGROUND

A semiconductor photolithography apparatus applies a desired pattern onto a substrate such as a wafer of semiconductor material, usually onto a target portion of the substrate. A patterning device, which is alternatively referred to as a mask or a reticle, may be used to generate a circuit pattern to be formed on part of an individual layer of the wafer. Transfer of the pattern is typically accomplished by imaging onto a layer of radiation-sensitive material (resist) provided on the substrate. In general, a single substrate will include adjacent target portions that are successively patterned.

Semiconductor photolithography apparatus includes so-called steppers, in which each target portion is irradiated by exposing an entire pattern onto the target portion at one time, and so-called scanners, in which each target portion is scanned by a beam of patterned radiation in a given direction while synchronously translating the substrate parallel or anti-parallel to this direction. It is also possible to transfer the pattern from the patterning device to the substrate by imprinting the pattern onto the substrate.

The light source used to illuminate the pattern and project the pattern onto the substrate can be in any one of a number of configurations. Deep ultraviolet excimer lasers commonly used in lithography systems include the krypton fluoride (KrF) laser at 248 nm wavelength and the argon fluoride (ArF) laser at 193 nm wavelength.

Lasers such as those described produce pulses of light. Each pulse of light is generated by a corresponding discharge pulse of electrical energy supplied to the laser by a pulsed power system. The lasers may have a single chamber or multiple chambers. A commonly used dual chamber configuration is the master oscillator power amplifier (“MOPA”) configuration that has two discharge chambers, a master oscillator (“MO”) discharge chamber and a power amplifier (“PA”) discharge chamber. The pulsed power systems for MOPA lasers that generate the electrical discharge pulses typically include a high voltage power supply, a resonant charging supply, an MO commutator module, an MO compression head module, a PA commutator module, and a PA compression head module. Single chamber lasers may use only a single commutator and a single compression head to supply discharge pulses to a single discharge chamber. In various implementations, a power amplifier may take the form of a single-pass amplifier, a double-pass amplifier, a power ring amplifier, a power oscillator, or other forms. Ancillary modules may include a laser control system that controls the operating voltage for electrodes in the discharge chamber and provides timing control for the pulsed power system.

These systems must be capable of generating pulses reproducibly and reliably. This can be a challenge for many reasons including that timing variations can be created by voltage and discharge timing errors in the pulsed power system and chambers. For example, some of these modules such as the commutators and compression heads include saturable reactors, such as saturable inductors, that function as magnetic switches. A saturable magnetic core within a saturable inductor gives the saturable inductor two distinct states. In one state the inductance and hence the impedance of the saturable reactor is high because the magnetic core has a high permeability. In the other state the inductance and hence the impedance is low because the magnetic core has been driven into saturation corresponding to a low permeability.

In order for a saturable inductor to function properly as a switching device in a magnetic pulse compression network, the core of the saturable inductor is initially biased at a point such as the negative saturation flux on its magnetic flux density (B) and magnetic field strength (H) curve (B-H curve or B-H loop). As voltage is applied across the inductor, the operating point of the magnetic core translates up the B-H curve until positive saturation flux is reached, at which point the inductor saturates and the desired closed switch functionality is realized. Before the saturable inductor can process the next pulse, however, the operating point of its core must be repositioned, or “reset,” at the original bias point.

Various factors may interfere, over time or from one laser to another, with a laser's ability to reset the bias point of a core within a saturable inductor. It is in this context that the need for the presently disclosed subject matter arises.

### SUMMARY

The following presents a summary of one or more embodiments in order to provide a basic understanding of the embodiments. This summary is not an extensive overview of all contemplated embodiments and is not intended to identify key or critical elements of all embodiments nor delineate the scope of any or all embodiments. Its sole purpose is to present some concepts of one or more embodiments in a concise form as a prelude to the more detailed description that is presented later.

According to an aspect of an embodiment, there is disclosed a pulsed power system including one or more pulsed bias reset circuits for the magnetic saturable reactor cores. The pulsed bias reset circuits make it possible to achieve consistent reset levels for the magnetic cores regardless of the prior state of the magnetic core or reset levels of magnetic cores. The pulsed bias circuit is designed to complete a full reset of the magnetic core material within the timing constraints imposed by the pulse-to-pulse and burst-to-burst timing intervals.

Further features and advantages of the present invention, as well as the structure and operation of various embodiments of the present invention, are described in detail below with reference to the accompanying drawings. It is noted that the present invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the present invention and, together with the description, further serve to explain the principles of the present invention and to enable a person skilled in the relevant art(s) to make and use the present invention.

FIG. 1 is a functional block diagram of a pulsed power circuit.

FIG. 2 is a circuit diagram for some components of a pulsed power circuit such as could be used in the arrangement of FIG. 1.

FIG. 3 is a typical B-H curve for a material for a saturable core according to an aspect of an embodiment.

FIG. 4 is a series of timing diagrams showing reset pulses having various characteristics according to an aspect of an embodiment.

FIG. 5 is a functional block diagram of a pulsed power circuit according to an aspect of an embodiment.

FIG. 6 is a flowchart depicting steps of a method of controlling the reset of magnetic cores in a pulsed power circuit according to an aspect of an embodiment.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

This specification discloses one or more embodiments that incorporate the features of the disclosed subject matter. The disclosed embodiment(s) merely exemplify the disclosed subject matter. The scope of the applicability of the disclosed subject matter is not limited to the disclosed embodiment(s). The scope of the present invention is defined by the claims forming part of this specification.

The embodiment(s) described, and references in the specification to “one embodiment”, “an embodiment”, “an example embodiment,” “an exemplary embodiment,” etc., indicate that the embodiment(s) described may include a particular feature, structure, or characteristic, but not every embodiment may necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to include such feature, structure, or characteristic in other embodiments whether or not such inclusion is explicitly described.

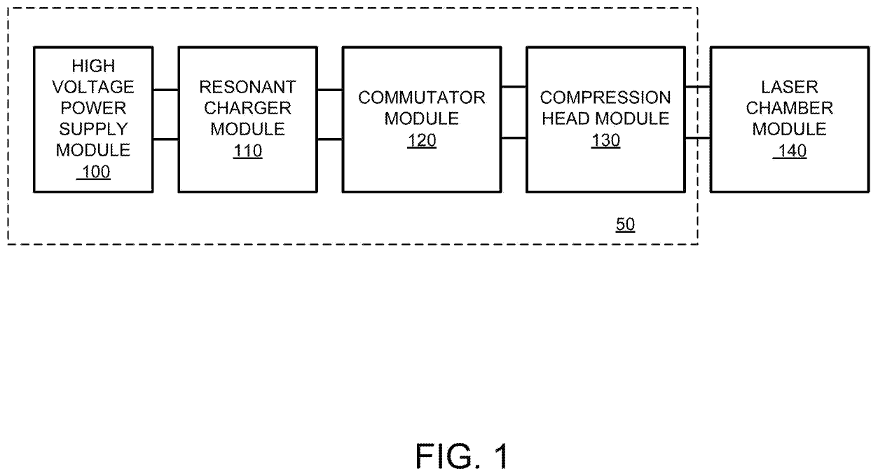

Turning to FIG. 1 there is shown an example of a pulsed power circuit 50 that includes a high voltage power supply module 100, a resonant charger module 110, a commutator module 120, and a compression head module 130. Pulsed power circuit 50 may be used to generate short and powerful pulses (e.g., in the 60-150 ns range and typical energy of 5-20 mJ per pulse) of electrical power. The electrical pulses may be supplied to electrodes in a laser chamber as discharge pulses in order to generate light pulses from the laser.

The output of the compression head module 130 may be supplied, for example, to a laser chamber module 140 which may be, for example, one chamber (MO or PA) of a so-called dual chamber system. In general, each discharge chamber is provided with its own respective pulsed power circuit 50. The pulsed power circuits 50 for each chamber, however, may share various elements such as a shared high voltage power supply module 100 and resonant charger module 110. The pulsed power circuit 50 may be configured as a solid state pulsed power module (SSPPM).

In operation, the high voltage power supply module 100 converts external power, e.g., three phase normal plant power to a high DC voltage. The resonant charger module 110 charges capacitor banks in the commutator module 120 to a regulated voltage to generate pulses. The commutator module 120 shortens the pulses and increases their voltage. The compression head module 130 further temporally compresses the electrical pulses from the commutator module 120 with a corresponding increase in current to produce pulses with the desired discharge voltage. These pulses are then applied across electrodes (not shown) in the laser chamber module 140. Additional details of arrangement and operation of such laser systems can be found, for example, in U.S. Pat. No. 7,079,564, titled “Control System for a Two Chamber Gas Discharge Laser” issued Jul. 18, 2006, the entire contents of which are incorporated by reference herein. Further details on the operation of this circuitry may be found in U.S. Pat. No. 7,002,443, titled “Method and Apparatus for Cooling Magnetic Circuit Elements” issued Feb. 21, 2006, the entire contents of which are incorporated by reference herein.

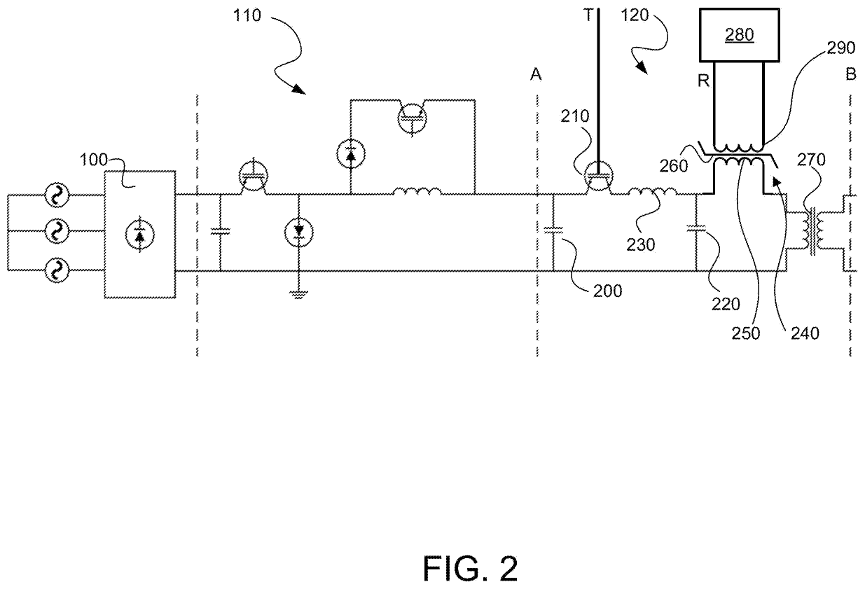

FIG. 2 is a simplified circuit diagram for certain components of an SSPPM connected to a high voltage power supply module 100, the SSPPM including a resonant charger module 110 and a commutator module 120 such as could be used in the pulsed power circuit of FIG. 1 according to an aspect of an embodiment. The elements between dashed lines A and B comprise the circuitry implementing the commutator module 120. The high voltage power supply module 100 supplies power to the resonant charger module 110 which operates in a known manner. The pulses from the resonant charger module 110 are supplied to the commutator module 120 to a charge capacitor 200. The capacitor 200 is usually referred to as C₀ and the voltage on the capacitor 200 is usually referred to as V_{C0}. When a trigger signal T is supplied to a commutator solid state switch 210, the commutator solid state switch 210 closes, discharging the capacitor 200 to a capacitor 220 through a charging inductance 230. The capacitor 220 is usually referred to as C₁ and the voltage across the capacitor 220 is usually referred to as V_{C1}. The voltage is held on the capacitor 220 until a saturable reactor 240, with its winding 250 and core 260 (shown schematically), functioning as a magnetic switch, saturates and discharges the capacitor 220 into a capacitor bank in the compression head module 130 (from FIG. 1) through a transformer 270. The compression head module 130 also typically contains one or more saturable reactors functioning as magnetic switches operating in a manner similar to that just described.

The saturable reactor 240 initially resists the flow of current from the capacitor 220. More specifically, normally, before an electrical discharge pulse is generated, the saturable reactor 240 is biased to negative saturation. When the next pulse of current comes from the capacitor 200 to charge the capacitor 220, the pulse of current induces an opposing electromotive force in the saturable reactor 240, which blocks the flow of the current pulse until the core 260 becomes saturated in the forward direction. Upon saturation, the opposing electromotive force disappears, and the charge accumulated on the capacitor 220 transfers through the saturable reactor 240 as if a circuit switch has suddenly closed.

Saturable reactor 240 thus functions as a magnetic switch for the pulsed laser. The saturable magnetic core gives the inductor two distinct states. In one state the inductance of the saturable reactor is high because the magnetic core has a high permeability. In the other state the inductance is low because the magnetic core has been driven into saturation, corresponding to a low permeability.

After the discharge pulse has reached the load, in this case the laser discharge chamber, the core of the magnetic switch remains biased at a point on the B-H curve near the positive saturation flux. Before the next discharge pulse can be generated, the core must be reset to the point on the B-H curve corresponding to the negative saturation flux.

As discussed above, before a saturable inductor can process the next pulse, the operating point of its core should be repositioned, or “reset,” at the original bias point. Depending on the reset time of the bias circuit, the inter-pulse time (time between pulses) and inter-burst time (time between bursts of pulses) may not allow for full or consistent reset of the magnetic cores in some conventional pulse power systems. This can result in different pulse-to-pulse (i.e., discharge pulse to discharge pulse) and burst-to-burst (i.e., bursts of multiple discharge pulses) reset levels, which will also impact the saturation timing of the magnetic cores.

There are additional variations in the pulsed power system and chamber that can influence the reset levels of the magnetic cores. These variations include the operating voltage applied to the electrodes in the chambers, chamber gas pressure, and magnetic core temperature. The first two parameters can have a direct impact on the reflected energy in the pulsed power system, which then impacts the reset timing and reset levels of the magnetic saturable reactors. There may also be variations in the core material properties, such as the material's saturation flux density, squareness, and coercivity.

Reliable discharge pulse-to-discharge pulse repeatability requires that the magnetic core be reset to the same pre-discharge-pulse state before each application of voltage to the inductor. As shown in FIG. 2, this resetting of the bias point of the saturable reactor may be carried out by a reset pulse R, an electrical pulse supplied by a reset circuit 280. In an arrangement such as that shown, reset is usually accomplished by causing a DC current to flow through an auxiliary winding 290 on the core 260 thereby providing the appropriate magnetization field (H) to bias the core 260 at the negative saturation flux. Alternatively, the reset circuit 280 may be connected directly to the main winding 250, eliminating the need for an auxiliary winding.

Often one circuit will be used to provide the reset current to multiple magnetic switches. The reset circuit typically provides a constant current to the reset winding during reset. Further details as to the function and design of reset circuits can be obtained, for example, from U.S. Pat. No. 5,184,085 issued Feb. 2, 1993, and titled “High Voltage Pulse Generating Circuit, and Discharge-Excited Laser and Accelerator Containing Such Circuit,” the entire specification of which is hereby incorporated by reference.

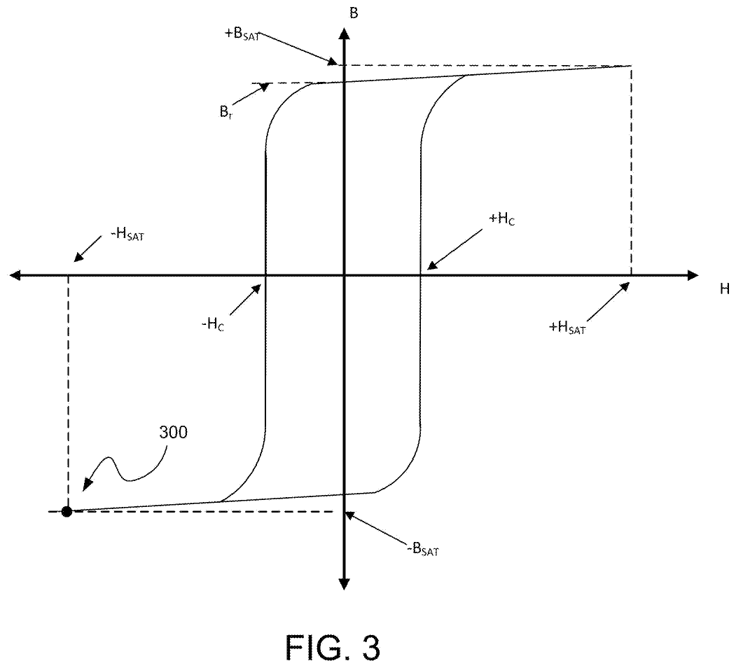

In other words, reset is achieved by magnetically restoring the core to a point such as point 300 in FIG. 3 which is an example of a B-H curve for a core material. Also shown in FIG. 3 is +H_{SAT}, which is the saturation value of the magnetic field strength H for which increases in H do not result in any further significant increases in the magnetic flux density B and −H_{SAT}, which is the saturation value of the magnetic field strength H for which decreases in H do not result in any further significant decreases in the magnetic flux density B. The respectively corresponding fluxes +B_{SAT} and −B_{SAT} are also shown. FIG. 3 also shows the magnetic remanence Br which is the flux density when the external magnetic field is zero, and +/− H_{c}, were “c” indicates coercivity, which is the magnitude of the magnetic field required to make the flux density B zero.

As mentioned, the saturable reactors in pulsed power systems are conventionally biased with a DC power source to allow for consistent reset of the reactor magnetic cores in the time intervals between the discharge pulses. Core reset may also be achieved with a reverse current pulse (a reset pulse) that occurs after the primary energy transfer of the discharge pulse is complete. Initially, the inductor receives a reset current pulse and the di/dt of the current pulse induces an opposite polarity voltage across the inductor. This opposite polarity voltage induces a decrease in flux density, driving the core into reverse saturation and resetting the core.

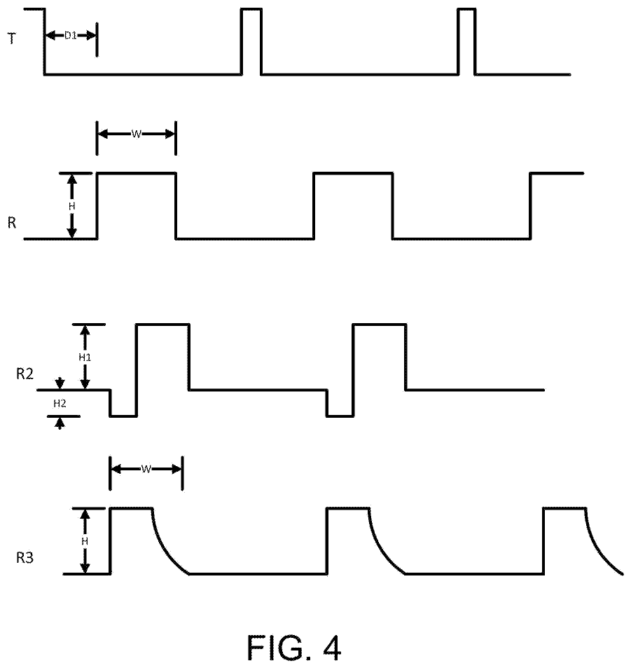

To be clear, several different types of pulses and signals are involved. One is the main or discharge pulse, which is the pulse of electricity developed by the pulsed power circuit and applied to a laser chamber to cause a discharge in the laser chamber and, hence, to produce a pulse of laser radiation. Another type is the trigger pulse or signal which is applied to the gate of commutator solid state switch 210 and identified as the signal T in FIG. 2 and FIG. 4 which initiates the discharge pulse. A third type is the reset pulse supplied by the reset circuit 280 and applied to saturable reactor 240 and identified as signal R in FIG. 2 and as R, R2, or R3 in FIG. 4 which resets the core to a desired saturation state in preparation for the generation of the next discharge pulse.

Proper reset of each magnetic switch is important for the repeatability of the discharge pulses. It is especially important when the output pulse of the magnetic compression network is constrained by tight timing and jitter requirements. As the repetition rate of the laser is increased, proper reset of each magnetic core becomes more critical and more challenging. This is principally because the interval between pulses is decreased and, as a result, there is less time for the reset dynamics to achieve a repeatable state. The problem of insuring that each core is properly reset may be compounded by residual energy in the pulse compression network as the discharge pulse propagates through. If not properly managed, this residual energy can be reflected back and forth in the network before it is dissipated, potentially hampering the reset of the magnetic switches, and potentially also affecting the saturation timing of the next and subsequent discharge pulses.

Variation in the bias current level can result in different reset levels of the magnetic cores, which will impact the saturation time of the saturable magnetic cores. Variations in bias reset levels may cause large burst timing variations, on the order of +/−5 ns. These variations can be even larger if a sufficient bias is not applied.

Additionally, depending on the reset time of the bias circuit, the inter-pulse time and inter-burst time may not allow for full or consistent reset of the magnetic cores in some conventional pulsed power systems. This can result in different discharge pulse-to- discharge pulse and burst-to-burst reset levels which will also impact the saturation timing of the magnetic cores.

In addition to variations caused by the bias supply and reset timing, there are also variations in the pulsed power system and chamber that can influence the reset levels of the magnetic cores. These variations include operating voltage of the electrodes, chamber pressure, and magnetic core properties and temperature. The first two of these variations can have a direct influence on the reflected energy in the pulsed power system which then influences the reset timing and reset levels of the magnetic saturable reactors. There may also be variations in the core material magnetic properties, such as the material's saturation flux density, squareness, and coercivity.

All of these variations can make it beneficial to apply a reset pulse that has characteristics such as timing offset from the discharge pulse, amplitude, duration, and shape suited to providing the same bias point repeatably (or a deliberately selected different bias point) for each discharge pulse. Timing of a discharge pulse within a burst can also be a factor in determining the optimal characteristics of the reset pulse.

Thus, a steady-state DC current or an electrical reset pulse having a single set of characteristics does not always afford sufficient control to repeatably return the saturable core to a desired bias position in the time available between pulses or bursts. Variations in the core materials and geometric dimensions, variations in core temperature, variations in reflected energy, variations in the voltage applied to the electrodes in the laser chambers, variations in chamber conditions such as gas pressure, and variations in the core material magnetic properties, such as the material's saturation flux density, squareness, and coercivity, as well as other factors may introduce variations in the reset dynamics that interfere with repeatability.

More specifically, a trigger signal applied to the gate of commutator solid state switch 210 in FIG. 2 triggers the process of charge transfer from the capacitor 200 to the capacitor 220. A timing diagram for one example of this trigger signal is shown as trace T in FIG. 4. The examples of traces in FIG. 4 are plotted as magnitude of signal levels (such as voltages) on the vertical axis versus time on the horizontal axis. Trace T shows an example of a trigger signal with a square pulse shape being repeated with each trigger signal initiating a discharge pulse. For example, the square pulses of trace T may be applied to the gate of commutator solid state switch 210 in FIG. 2 to initiate a discharge pulse that transfers charge from the capacitor 200 to the capacitor 210.

The reset pulses may be applied by the reset circuit 280 when the trigger signal T is low, i.e., between the trigger signal pulses that cause the discharge pulse to occur. Also shown in FIG. 4 is an example of a reset pulse trace labeled R. As shown, the reset pulses may be essentially square wave pulses. Various characteristics of the reset pulse such as the magnitude and sign of its amplitude H, its width W, and the amount of offset time DI that the reset pulse is offset from the trigger pulse, may all affect the reset dynamics. As regards the magnitude and sign of the reset pulse amplitude, in most cases the reset pulse will be unipolar with a polarity that is opposite in sign to the polarity of the discharge pulse. In some implementations, however, it could be advantageous for the reset pulse to be bipolar, for example, to drive the core further into forward saturation before driving the core to reverse saturation. An example of a waveform to accomplish this is shown as trace R2 in FIG. 4 with a portion having a positive amplitude (positive polarity) HI and a portion having a negative amplitude (negative polarity) H2. It will be apparent that the reset pulses are not necessarily square or symmetrical. Trace R3 of FIG. 4 is an example of a train of reset pulses that are neither square nor symmetrical.

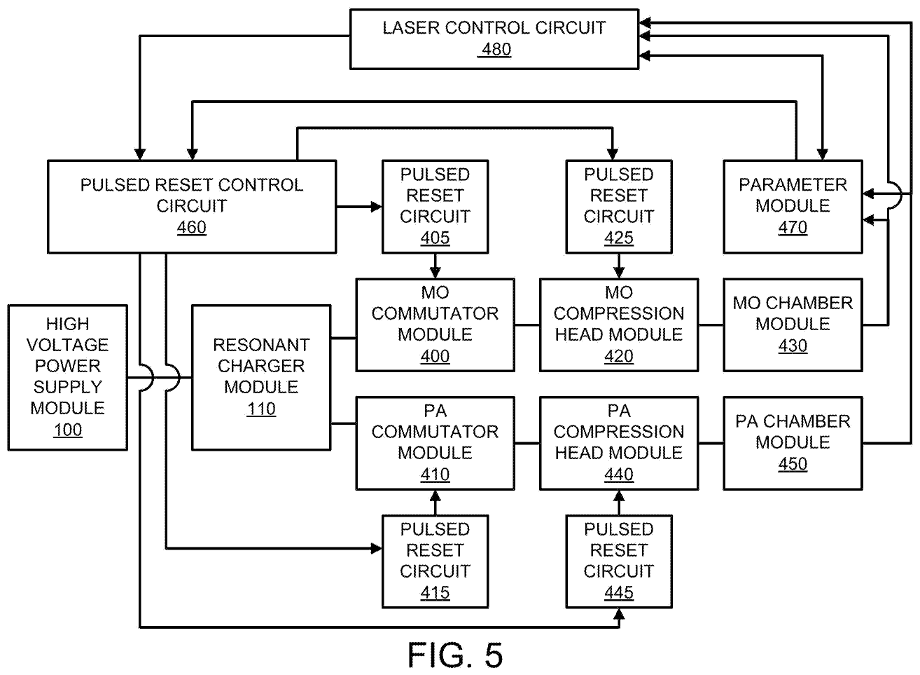

As shown in FIG. 5, a pulsed laser source including a pulsed power supply system according to one aspect of an embodiment may include a high voltage power supply module 100 and a resonant charger module 110 as described above. In the example of the dual chamber design shown in FIG. 5, the system also includes an MO commutator module 400 and a PA commutator module 410. The MO commutator module 400 supplies an electrical pulse to an MO compression head module 420 as described above which compresses the electrical pulse and supplies it to an MO chamber module 430. Similarly, the PA commutator module 410 creates a pulse that is compressed by a PA compression head module 440 which is then supplied to a PA chamber module 450.

According to an aspect of an embodiment, a saturable reactor in the MO commutator module 400 is reset by a pulsed reset circuit 405. A saturable reactor included in the PA commutator module 410 is reset by a pulsed reset circuit 415. Similarly, a saturable reactor in the MO compression head module 420 is reset by pulsed reset circuit 425. A saturable reactor in the PA compression head module 440 is reset by a pulse reset circuit 445. The pulse reset circuits 405, 415, 425, and 445 operate under the control of a pulsed reset control circuit 460. The pulsed reset control circuit 460 may be part of an overall control circuit for the system or may be separately dedicated circuitry.

Although this example describes only one saturable reactor respectively in connection with each of the commutator and compression head modules, it will be understood that each of these modules may include multiple saturable reactors which would benefit from controlled reset.

In some embodiments the pulsed reset control circuit 460 receives information from a parameter module 470 such as, for example, the electrode voltage and chamber gas pressure in the MO chamber module 430 and the electrode voltage and chamber gas pressure in the PA chamber module 450. The pulsed reset control circuit 460 can then determine the characteristics of the reset pulses it will supply based on this information. For example, the pulsed reset control circuit 460 can control one or more of the timing, amplitude, polarity, duration, and shape of the reset pulses which will best reset their respective associated saturable reactors. Also, the pulsed reset control circuit 460 is capable of controlling the relative timing of the reset pulses to optimize the resetting of the various saturable reactors.

In some embodiments, the inputs to the pulsed reset control circuit 460 need not be determined separately but instead may be obtained from other diagnostics in the laser. For example, these data may be obtained from an overall laser control circuit 480 that already has data from a chamber temperature sensor for a chamber temperature diagnostic. Also, the laser control circuit 480 can determine the electrode voltage as a scaled version of the programmed electrode voltage. Thus, in FIG. 5, the inputs for the parameter module 470 may come from the laser control circuit 480, and the parameter module 470 may communicate control signals for the pulsed reset control circuit 460 directly to the pulsed reset control circuit 460 or through the laser control circuit 480. Alternatively, the laser control circuit 480 may determine the control signals directly from the information available to the laser control circuit 480, thus dispensing with or limiting the need for the parameter module 470.

Alternatively, as mentioned, the parameter module 470 may obtain data from the laser control circuit 480 and supply it to the pulsed reset control circuit 460 so that the parameter module 470 obtains its data from the laser control circuit 480 rather than directly from dedicated sensors. Of course, these are simply examples of many possible arrangements and distributions of functionality. It will be apparent to one of ordinary skill in the art that other arrangements could also be used.

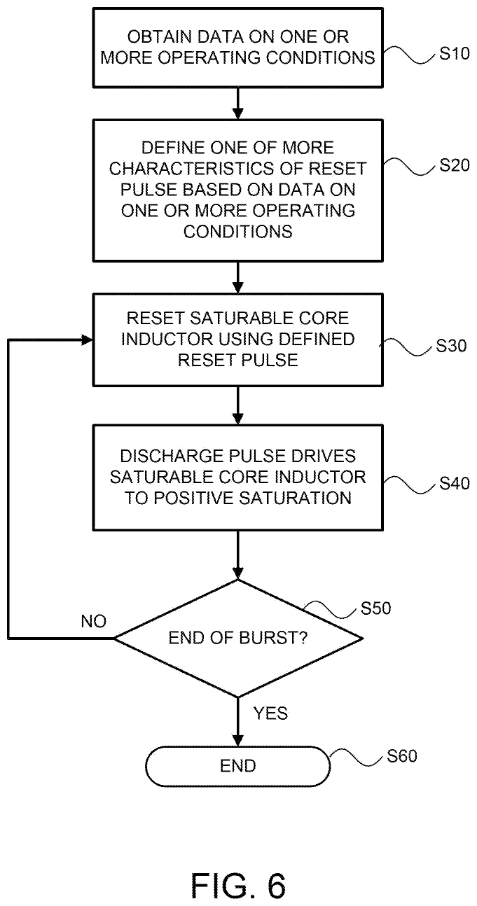

FIG. 6 is a flow chart describing aspects of operation of a reset pulse generation system according to aspects of certain embodiments. The procedure described in FIG. 6 may be initiated, for example, at the beginning of a burst of laser light pulses. As shown in FIG. 6, in a step S10, data pertaining to one or more operating conditions such as electrode operating voltage or chamber pressure are obtained. Then, in a step S20, one or more characteristics of the reset pulse are defined using the data obtained in the step S10. The characteristics of the reset pulse that are defined may include offset, amplitude, duration, and shape. In a step S30 the saturable core inductor is reset using the reset pulse. Then, in a step S40, the saturable core inductor is driven to positive saturation by the discharge pulse. In a step S50 it is determined whether the discharge pulse was the end of a burst. If the discharge pulse was the end of the burst, then, in a step S60 the process is terminated. If in the step S50 is determined that the pulse was not the end of a burst, then the process reverts to the step S30 and the saturable core is again reset using the reset pulse.

As a specific example, in the step S10 the procedure may obtain the electrode operating voltage as an operating condition and then the step S20 may use the electrode operating voltage to define the duration of the reset pulse.

The above is one example of control of reset pulses. These reset pulses may be applied to any one or more of the magnetic cores mentioned above. It is also possible that other magnetic cores or other groups of magnetic cores would respectively use different associated reset pulses. It is also possible that the characteristics of reset pulse could be determined heuristically to be selected to be those that yield the most reliably repeatable and consistent reset operations.

The above is an example of an embodiment in which the characteristics of the reset pulse are defined on a burst-to-burst basis. It will be apparent to one of ordinary skill in the art, however, that the procedure of FIG. 6 may be used to define the characteristics of the reset pulses for multiple bursts. It will also be apparent to one of ordinary skill in the art that the characteristics for the reset pulse may be defined intra-burst so that they can be adjusted on a discharge pulse-to-discharge pulse basis.

Thus, disclosed herein is a system comprising a first laser subsystem configured to produce a pulsed seed laser beam, the first laser subsystem comprising a first chamber configured to hold a first gaseous gain medium and a first excitation mechanism in the first chamber. A second laser subsystem is configured to produce a pulsed output laser beam based on the pulsed seed laser beam, the second optical subsystem comprising a second chamber configured to hold a second gaseous gain medium and a second excitation mechanism in the second chamber. A first magnetic switching network is configured to activate, i.e., induce excitation in, the first excitation mechanism. The first magnetic switching network comprises a first magnetic core associated with a first impedance characteristic, e.g., magnetic flux density (B) versus magnetic field strength (H) for the magnetic core. Activating the first excitation mechanism causes the first optical subsystem to produce a pulse of the pulsed seed laser beam. A second magnetic switching network is configured to activate the second excitation mechanism. The second magnetic switching network comprises a second magnetic core associated with a second impedance characteristic. A first bias circuit is configured to magnetically couple to the first magnetic core and a second bias circuit is configured to magnetically couple to the second magnetic core. A controller is configured to adjust an impedance of the first magnetic core by causing the first bias circuit to produce a first electrical reset current pulse. One or more characteristics of the first electrical reset current pulse are based on a first operating condition of the first laser subsystem. The controller is additionally configured to adjust an impedance of the second magnetic core by causing the second bias circuit to produce a second electrical reset current pulse. One or more characteristics of the second electrical reset current pulse are based on a second operating condition of the second laser subsystem.

The one or more characteristics of the first electrical reset current pulse may include an amplitude of the first electrical reset current pulse. The controller may then determine the amplitude of the first electrical reset current pulse based on the first operating condition, with the impedance of the first magnetic core depending on the amplitude of the first electrical reset current pulse. Similarly, the one or more characteristics of the second electrical reset current pulse may comprise an amplitude of the second electrical reset current pulse. The controller may then determine the amplitude of the second electrical reset current pulse based on the second operating condition, with the impedance of the second magnetic core depending on the amplitude of the second electrical reset current pulse.

The one or more characteristics of the first electrical reset current pulse may comprise an amplitude and/or a temporal duration of the first electrical reset current pulse. The controller may then determine the amplitude and/or the temporal duration of the first electrical reset current pulse based on the first operating condition, the impedance of the first magnetic core depending on the amplitude of the first electrical reset current pulse, and the time required for the impedance of the first magnetic core to be adjusted depending on the temporal duration of the first electrical reset current pulse. Similarly, the one or more characteristics of the second electrical reset current pulse may comprise an amplitude of the second electrical reset current pulse and/or a temporal duration of the second electrical reset current pulse. The controller may then determine the amplitude of the second electrical reset current pulse and/or the temporal duration of the second electrical reset current pulse based on the second operating condition, the impedance of the second magnetic core depending on the amplitude of the second electrical reset current pulse, and the time required for the impedance of the second magnetic core to be adjusted depending on the temporal duration of the second electrical reset current pulse.

The amplitude of the first electrical reset current pulse and the amplitude of the second electrical reset current pulse may be the same, or they may be different. The controller may be configured to adjust the impedance of the first magnetic core before each pulse of the pulsed seed laser beam is produced, and to adjust the impedance of the second magnetic core before each pulse of the pulsed output laser beam is produced.

The first impedance characteristic may comprise a first relationship between magnetic flux density versus magnetic field strength, and hence, a relationship between magnetic field strength and permeability and so inductance of the first magnetic core. The second impedance characteristic may comprise a second relationship between magnetic flux density versus magnetic field strength, and hence, a relationship between magnetic field strength and permeability and so inductance of the second magnetic core.

The first laser subsystem may comprise a master oscillator, and the second optical subsystem may comprise a power amplifier. The power amplifier may comprise a power ring amplifier. The power amplifier may comprise a power oscillator. The pulsed seed laser beam and pulsed output laser beam may both comprise one or more wavelengths in the deep ultraviolet (DUV) range.

The first bias circuit may be further configured to provide a first bias current which may have a constant amplitude during reset, and the second bias circuit may be further configured to provide a constant second bias current which may have a constant amplitude during reset. The first bias circuit may be further or alternatively configured to provide a pulsed first bias current, and the second bias circuit may be further or alternatively configured to provide a pulsed second bias current.

Thus, also disclosed herein is a controller comprising a trigger module configured to provide a first initiation trigger signal to a first magnetic switching network, the first initiation trigger signal causing a first magnetic core in the first magnetic switching network to saturate such that the first magnetic switching network activates a gain excitation mechanism in a first laser subsystem and provide a second initiation trigger signal to a second magnetic switching network. The controller is also configured to provide a second initiation trigger signal causing a second magnetic core in the second magnetic switching network to saturate such that the second magnetic switching network activates a gain excitation mechanism in a second laser subsystem. The controller also comprises an electrical current module configured to determine one or more characteristics of a first electrical reset current pulse based on a first operating condition, wherein the first electrical reset current pulse is configured to adjust an impedance of the saturated first magnetic core to a first reset level, and determine one or more characteristics of a second electrical reset current pulse based on second operating condition, wherein the second electrical current is pulse configured to adjust an impedance of the second magnetic core to a second reset level.

Activating the gain mechanism in the first optical subsystem produces a pulse of a seed laser beam and activating the gain mechanism in the second optical subsystem amplifies the pulse of the seed laser beam. In an embodiment, the electrical current module is configured to adjust the impedance of the saturated first magnetic core to the first reset level each time the gain excitation mechanism in the first optical subsystem is activated and to adjust the impedance of the saturated second magnetic core to the second reset level each time the gain excitation mechanism in the second subsystem is activated. The one or more properties of the first electrical reset current pulse comprises a first amplitude and/or a first temporal duration, and the one or more properties of the second electrical current comprises a second amplitude and/or a second temporal duration.

Thus also disclosed is a method of controlling an impedance of a magnetic core in a laser system that produces a pulsed laser beam, the method comprising determining one or more characteristics of a pulsed reset electrical current based on an operating condition of the laser, adjusting the impedance of the magnetic core to a reset level by providing the pulsed reset electrical current to a coil that is magnetically coupled to the magnetic core, and after adjusting the impedance of the magnetic core, producing a pulse of laser radiation, wherein producing a pulse of laser radiation comprises saturating the magnetic core such that an electrical pulse is provided to an excitation mechanism of the laser system.

The one or more characteristics of the pulsed reset electrical reset current pulse may comprise an amplitude. The reset pulse may reset the impedance of the magnetic core to the same value before producing each pulse of laser radiation in a plurality of pulses of laser radiation. The amplitude or the temporal duration or both of the pulsed reset electrical current provided to the coil before producing a first one of the plurality of pulses of laser radiation may be different from the amplitude or the temporal duration of the reset electrical current provided to the coil before producing a second one of the plurality of pulses of laser radiation. The first one of the plurality of pulses of laser radiation may be a first pulse of laser radiation in a burst of pulses of laser radiation, and the second one of the plurality of pulses of laser radiation may be a later pulse of laser radiation in the same burst of pulses of laser radiation. The plurality of pulses of laser radiation may be consecutive pulses of laser radiation in a single burst of pulses of laser radiation.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventors, and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions are appropriately performed.

The foregoing description of the specific embodiments will so fully reveal the general nature of the present invention that others can, by applying knowledge within the skill of the art, readily modify and/or adapt for various applications such specific embodiments, without undue experimentation, without departing from the general concepts of the present invention. Therefore, such modifications and adaptations are intended to be within the meaning of the language used to describe the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance provided herein.

The embodiments can be further described using the following clauses:

1. A system comprising:
a first laser subsystem configured to produce a pulsed seed laser beam, the first laser subsystem comprising:
a first chamber configured to hold a first gain medium; and
a first excitation mechanism in the first chamber;
a second laser subsystem configured to produce a pulsed output laser beam based on the pulsed seed laser beam, the second optical subsystem comprising:
a second chamber configured to hold a second gain medium; and
a second excitation mechanism in the second chamber;
a first magnetic switching network configured to activate the first excitation mechanism, wherein the first magnetic switching network comprises a first magnetic core, and activating the first excitation mechanism causes the first optical subsystem to produce a pulse of the pulsed seed laser beam; and
a second magnetic switching network configured to activate the second excitation mechanism, wherein the second magnetic switching network comprises a second magnetic core, and activating the second excitation mechanism causes the second optical subsystem to produce a pulse of the pulsed output laser beam;
a first bias circuit configured to electrically or magnetically couple to the first magnetic core;
a second bias circuit configured to electrically or magnetically couple to the second magnetic core; and
a controller configured to
adjust an impedance of the first magnetic core by causing the first bias circuit to produce a first electrical reset current pulse, wherein one or more characteristics of the first electrical reset current pulse are based on an operating condition of the first laser subsystem; and
adjust an impedance of the second magnetic core by causing the second bias circuit to produce a second electrical reset current pulse, wherein one or more characteristics of the second electrical reset current pulse are based on an operating condition of the second laser subsystem.
   2. The system of clause 1,
wherein the one or more characteristics of the first electrical reset current pulse comprises an amplitude of the first electrical reset current pulse, wherein the controller determines the amplitude of the first electrical reset current pulse based on the operating condition of the first laser subsystem, and the impedance of the first magnetic core depends on the amplitude of the first electrical reset current pulse; and
the one or more characteristics of the second electrical reset current pulse comprises an amplitude of the second electrical reset current pulse, the controller determines the amplitude of the second electrical reset current pulse based on the operating condition of the second laser subsystem, and the impedance of the second magnetic core depends on the amplitude of the second electrical reset current pulse.
   3. The system of clause 1, wherein
the one or more characteristics of the first electrical reset current pulse comprises an amplitude and a temporal duration of the first electrical reset current pulse, wherein the controller determines the amplitude and the temporal duration of the first electrical reset current pulse based on the operating condition of the first laser subsystem, wherein the impedance of the first magnetic core depends on the amplitude of the first electrical reset current pulse, and wherein the time required for the impedance of the first magnetic core to be adjusted depends on the temporal duration of the first electrical reset current pulse; and
wherein the one or more characteristics of the second electrical reset current pulse comprises an amplitude of the second electrical reset current pulse and a temporal duration of the second electrical reset current pulse, the controller determines the amplitude of the second electrical reset current pulse and the temporal duration of the second electrical reset current pulse based on the operating condition of the second laser subsystem, wherein the impedance of the second magnetic core depends on the amplitude of the second electrical reset current pulse, and wherein the time required for the impedance of the second magnetic core to be adjusted depends on the temporal duration of the second electrical reset current pulse.
   4. The system of clause 3, wherein the amplitude of the first electrical reset current pulse and the amplitude of the second electrical reset current pulse are different from each other.
   5. The system of clause 1, wherein the controller is configured to adjust the impedance of the first magnetic core before each pulse of the pulsed seed laser beam is produced, and to adjust the impedance of the second magnetic core before each pulse of the pulsed output laser beam is produced.
   6. The system of clause 1, wherein the first laser subsystem comprises a master oscillator, and the second optical subsystem comprises a power amplifier.
   7. The system of clause 6, wherein the power amplifier comprises a power ring amplifier.
   8. The system of clause 1, wherein the pulsed seed laser beam and the pulsed output laser beam both comprise one or more wavelengths in the deep ultraviolet (DUV) range.
   9. A controller comprising:
a trigger module configured to:
provide a first initiation trigger signal to a first magnetic switching network, the first initiation trigger signal causing a first magnetic core in the first magnetic switching network to saturate such that the first magnetic switching network activates a gain excitation mechanism in a first laser subsystem;
provide a second initiation trigger signal to a second magnetic switching network, the second initiation trigger signal causing a second magnetic core in the second magnetic switching network to saturate such that the second magnetic switching network activates a gain excitation mechanism in a second laser subsystem; and
an electrical current module configured to:
determine one or more characteristics of a first electrical reset current pulse based on an operating condition of the first laser subsystem, wherein the first electrical reset current pulse is configured to adjust an impedance of the first magnetic core to a first reset level; and
determine one or more characteristics of a second electrical reset current pulse based on an operating condition of the second laser subsystem, wherein the second electrical reset current pulse is configured to adjust an impedance of the second magnetic core to a second reset level.
   10. The controller of clause 9, wherein activating the gain mechanism in the first optical subsystem produces a pulse of a seed laser beam and activating the gain mechanism in the second optical subsystem amplifies the pulse of the seed laser beam.
   11. The controller of clause 9, wherein the electrical current module is configured to adjust the impedance of the first magnetic core to the first reset level each time the gain excitation mechanism in the first optical subsystem is activated and to adjust the impedance of the second magnetic core to the second reset level each time the gain excitation mechanism in the second subsystem is activated.
   12. The controller of clause 9, wherein the one or more characteristics of the first electrical reset current pulse comprises a first amplitude and a first temporal duration, and the one or more characteristics of the second electrical reset current pulse comprises a second amplitude and a second temporal duration.
   13. A method of controlling an impedance of a magnetic core in a laser system that produces a pulsed laser beam, the method comprising: determining one or more characteristics of an electrical reset current pulse based on an operating condition of the first laser subsystem;
adjusting the impedance of the magnetic core to a reset level by providing the electrical reset current pulse to a coil that is magnetically coupled to the magnetic core; and
after adjusting the impedance of the magnetic core, producing a pulse of laser radiation, wherein producing a pulse of laser radiation comprises saturating the magnetic core such that a discharge electrical pulse is provided to an excitation mechanism of the laser system.
   14. The method of clause 13, wherein the one or more characteristics of the electrical reset current pulse comprise an amplitude of the electrical reset current pulse.
   15. The method of clause 13, wherein the electrical reset current pulse resets the impedance of the magnetic core to the same value before producing each of a plurality of pulses of laser radiation.
   16. The method of clause 15, wherein the amplitude or the temporal duration of the electrical reset current pulse provided to the coil before producing a first one of the plurality of pulses of laser radiation is different from the amplitude or the temporal duration of the reset electrical reset current pulse provided to the coil before producing a second one of the plurality of pulses of laser radiation.
   17. The method of clause 16, wherein the first one of the plurality of pulses of laser radiation is a first pulse of laser radiation in a burst of pulses of laser radiation, and the second one of the plurality of pulses of laser radiation is a later pulse of laser radiation in the same burst of pulses of laser radiation.
   18. The method of clause 15, wherein the plurality of pulses of laser radiation are consecutive pulses in a single burst of pulses of laser radiation.
   19. A pulsed power system for supplying discharge pulses to a laser discharge chamber, the pulsed power system comprising:
a compression head module including a compression head module magnetic switch having a compression head module saturable reactor;
a compression head module reset circuit adapted to supply a compression head module reset pulse to the compression head module saturable reactor to reset an operating point of the compression head module saturable reactor to a predetermined compression head bias point; and
a reset circuit control module arranged to control operation of the compression head reset circuit based on at least one operating condition in the laser discharge chamber.
   20. A pulsed power system for supplying discharge pulses including master oscillator (“MO”) discharge pulses to an MO laser chamber, the pulsed power system comprising:
an MO compression head module including an MO compression head module magnetic switch having an MO compression head module saturable reactor;
an MO compression head module reset circuit adapted to supply an MO compression head module reset pulse to the MO compression head module saturable reactor to reset an operating point of the MO compression head module saturable reactor to a predetermined MO compression head bias point; and
a reset circuit control module arranged to control operation of the MO compression head reset circuit based on at least one condition in the MO laser chamber.
   21. The pulsed power system of clause 20 further comprising
an MO commutator module arranged to provide MO commutator pulses to the MO compression head module, the MO commutator module including an MO commutator module magnetic switch having an MO commutator module saturable reactor; and
an MO commutator module reset circuit adapted to supply an MO commutator module reset pulse to the MO commutator module saturable reactor to reset an operating point of the MO compression head module saturable reactor to a predetermined MO commutator bias point,
the reset circuit control module being further arranged to control operation of the MO commutator module reset circuit based on at least one condition in the MO laser chamber.
   22. The pulsed power system of clause 20 further comprising:
a power amplifier (“PA”) compression head module including an PA compression head module magnetic switch having a PA compression head module saturable reactor;
a PA compression head module reset circuit adapted to supply a PA compression head module pulse to the PA compression head module saturable reactor to reset an operating point of the PA
compression head module saturable reactor to a predetermined PA compression head bias point; a PA commutator module arranged to provide PA commutator pulses to the PA compression head module, the PA commutator module including a PA commutator module magnetic switch having a
PA commutator module saturable reactor; and
a PA commutator module reset circuit adapted to supply a PA commutator module pulse to the PA commutator head module saturable reactor to reset an operating point of the PA commutator module saturable reactor to a predetermined PA commutator bias point,
the reset circuit control module being further arranged to control operation of the PA compression head reset circuit based on at least one condition in the PA laser chamber and to control operation of the PA commutator reset circuit based on at least one condition in the PA laser chamber.

Still other implementations are within the scope of the following claims.

What is claimed is:

1. A system comprising:
a first laser subsystem configured to produce a pulsed seed laser beam, the first laser subsystem comprising:
a first chamber configured to hold a first gain medium; and
a first excitation mechanism in the first chamber;
a second laser subsystem configured to produce a pulsed output laser beam based on the pulsed seed laser beam, the second optical subsystem comprising:
a second chamber configured to hold a second gain medium; and
a second excitation mechanism in the second chamber;
a first magnetic switching network configured to activate the first excitation mechanism, wherein the first magnetic switching network comprises a first magnetic core, and activating the first excitation mechanism causes the first optical subsystem to produce a pulse of the pulsed seed laser beam; and
a second magnetic switching network configured to activate the second excitation mechanism, wherein the second magnetic switching network comprises a second magnetic core, and activating the second excitation mechanism causes the second optical subsystem to produce a pulse of the pulsed output laser beam;
a first bias circuit configured to electrically or magnetically couple to the first magnetic core;
a second bias circuit configured to electrically or magnetically couple to the second magnetic core; and
a controller configured to
adjust an impedance of the first magnetic core by causing the first bias circuit to produce a first electrical reset current pulse, wherein one or more characteristics of the first electrical reset current pulse are based on an operating condition of the first laser subsystem; and
adjust an impedance of the second magnetic core by causing the second bias circuit to produce a second electrical reset current pulse, wherein one or more characteristics of the second electrical reset current pulse are based on an operating condition of the second laser subsystem.

2. The system of claim 1,
wherein the one or more characteristics of the first electrical reset current pulse comprises an amplitude of the first electrical reset current pulse, wherein the controller determines the amplitude of the first electrical reset current pulse based on the operating condition of the first laser subsystem, and the impedance of the first magnetic core depends on the amplitude of the first electrical reset current pulse; and
the one or more characteristics of the second electrical reset current pulse comprises an amplitude of the second electrical reset current pulse, the controller determines the amplitude of the second electrical reset current pulse based on the operating condition of the second laser subsystem, and the impedance of the second magnetic core depends on the amplitude of the second electrical reset current pulse.

3. The system of claim 1, wherein
the one or more characteristics of the first electrical reset current pulse comprises an amplitude and a temporal duration of the first electrical reset current pulse, wherein the controller determines the amplitude and the temporal duration of the first electrical reset current pulse based on the operating condition of the first laser subsystem, wherein the impedance of the first magnetic core depends on the amplitude of the first electrical reset current pulse, and wherein the time required for the impedance of the first magnetic core to be adjusted depends on the temporal duration of the first electrical reset current pulse; and
wherein the one or more characteristics of the second electrical reset current pulse comprises an amplitude of the second electrical reset current pulse and a temporal duration of the second electrical reset current pulse, the controller determines the amplitude of the second electrical reset current pulse and the temporal duration of the second electrical reset current pulse based on the operating condition of the second laser subsystem, wherein the impedance of the second magnetic core depends on the amplitude of the second electrical reset current pulse, and wherein the time required for the impedance of the second magnetic core to be adjusted depends on the temporal duration of the second electrical reset current pulse.

4. The system of claim 3, wherein the amplitude of the first electrical reset current pulse and the amplitude of the second electrical reset current pulse are different from each other.

5. The system of claim 1, wherein the controller is configured to adjust the impedance of the first magnetic core before each pulse of the pulsed seed laser beam is produced, and to adjust the impedance of the second magnetic core before each pulse of the pulsed output laser beam is produced.

6. The system of claim 1, wherein the first laser subsystem comprises a master oscillator, and the second optical subsystem comprises a power amplifier.

7. The system of claim 6, wherein the power amplifier comprises a power ring amplifier.

8. The system of claim 1, wherein the pulsed seed laser beam and the pulsed output laser beam both comprise one or more wavelengths in the deep ultraviolet (DUV) range.

9. A controller comprising:
a trigger module configured to:
provide a first initiation trigger signal to a first magnetic switching network, the first initiation trigger signal causing a first magnetic core in the first magnetic switching network to saturate such that the first magnetic switching network activates a gain excitation mechanism in a first laser subsystem;
provide a second initiation trigger signal to a second magnetic switching network, the second initiation trigger signal causing a second magnetic core in the second magnetic switching network to saturate such that the second magnetic switching network activates a gain excitation mechanism in a second laser subsystem; and
an electrical current module configured to:
determine one or more characteristics of a first electrical reset current pulse based on an operating condition of the first laser subsystem, wherein the first electrical reset current pulse is configured to adjust an impedance of the first magnetic core to a first reset level; and
determine one or more characteristics of a second electrical reset current pulse based on an operating condition of the second laser subsystem, wherein the second electrical reset current pulse is configured to adjust an impedance of the second magnetic core to a second reset level.

10. The controller of claim 9, wherein activating the gain mechanism in the first optical subsystem produces a pulse of a seed laser beam and activating the gain mechanism in the second optical subsystem amplifies the pulse of the seed laser beam.

11. The controller of claim 9, wherein the electrical current module is configured to adjust the impedance of the first magnetic core to the first reset level each time the gain excitation mechanism in the first optical subsystem is activated and to adjust the impedance of the second magnetic core to the second reset level each time the gain excitation mechanism in the second subsystem is activated.

12. The controller of claim 9, wherein the one or more characteristics of the first electrical reset current pulse comprises a first amplitude and a first temporal duration, and the one or more characteristics of the second electrical reset current pulse comprises a second amplitude and a second temporal duration.

13. A method of controlling an impedance of a magnetic core in a laser system that produces a pulsed laser beam, the method comprising:
determining one or more characteristics of an electrical reset current pulse based on an operating condition of the first laser subsystem;
adjusting the impedance of the magnetic core to a reset level by providing the electrical reset current pulse to a coil that is magnetically coupled to the magnetic core; and
after adjusting the impedance of the magnetic core, producing a pulse of laser radiation, wherein producing a pulse of laser radiation comprises saturating the magnetic core such that a discharge electrical pulse is provided to an excitation mechanism of the laser system.

14. The method of claim 13, wherein the one or more characteristics of the electrical reset current pulse comprise an amplitude of the electrical reset current pulse.

15. The method of claim 13, wherein the electrical reset current pulse resets the impedance of the magnetic core to the same value before producing each of a plurality of pulses of laser radiation.

16. The method of claim 15, wherein the amplitude or the temporal duration of the electrical reset current pulse provided to the coil before producing a first one of the plurality of pulses of laser radiation is different from the amplitude or the temporal duration of the reset electrical reset current pulse provided to the coil before producing a second one of the plurality of pulses of laser radiation.

17. The method of claim 16, wherein the first one of the plurality of pulses of laser radiation is a first pulse of laser radiation in a burst of pulses of laser radiation, and the second one of the plurality of pulses of laser radiation is a later pulse of laser radiation in the same burst of pulses of laser radiation.

18. The method of claim 15, wherein the plurality of pulses of laser radiation are consecutive pulses in a single burst of pulses of laser radiation.

19. A pulsed power system for supplying discharge pulses to a laser discharge chamber, the pulsed power system comprising:
a compression head module including a compression head module magnetic switch having a compression head module saturable reactor;
a compression head module reset circuit adapted to supply a compression head module reset pulse to the compression head module saturable reactor to reset an operating point of the compression head module saturable reactor to a predetermined compression head bias point; and
a reset circuit control module arranged to control operation of the compression head reset circuit based on at least one operating condition in the laser discharge chamber.

20. A pulsed power system for supplying discharge pulses including master oscillator (“MO”) discharge pulses to an MO laser chamber, the pulsed power system comprising:
an MO compression head module including an MO compression head module magnetic switch having an MO compression head module saturable reactor;
an MO compression head module reset circuit adapted to supply an MO compression head module reset pulse to the MO compression head module saturable reactor to reset an operating point of the MO compression head module saturable reactor to a predetermined MO compression head bias point; and
a reset circuit control module arranged to control operation of the MO compression head reset circuit based on at least one condition in the MO laser chamber.

21. The pulsed power system of claim 20 further comprising
an MO commutator module arranged to provide MO commutator pulses to the MO compression head module, the MO commutator module including an MO commutator module magnetic switch having an MO commutator module saturable reactor; and
an MO commutator module reset circuit adapted to supply an MO commutator module reset pulse to the MO commutator module saturable reactor to reset an operating point of the MO compression head module saturable reactor to a predetermined MO commutator bias point,
the reset circuit control module being further arranged to control operation of the MO commutator module reset circuit based on at least one condition in the MO laser chamber.

22. The pulsed power system of claim 20 further comprising:
a power amplifier (“PA”) compression head module including an PA compression head module magnetic switch having a PA compression head module saturable reactor;
a PA compression head module reset circuit adapted to supply a PA compression head module pulse to the PA compression head module saturable reactor to reset an operating point of the PA compression head module saturable reactor to a predetermined PA compression head bias point;
a PA commutator module arranged to provide PA commutator pulses to the PA compression head module, the PA commutator module including a PA commutator module magnetic switch having a PA commutator module saturable reactor; and
a PA commutator module reset circuit adapted to supply a PA commutator module pulse to the PA commutator head module saturable reactor to reset an operating point of the PA commutator module saturable reactor to a predetermined PA commutator bias point,
the reset circuit control module being further arranged to control operation of the PA compression head reset circuit based on at least one condition in the PA laser chamber and to control operation of the PA commutator reset circuit based on at least one condition in the PA laser chamber.
